(19) United States
(12) Patent Application Publication
(10) Pub. No.: US 2023/0065976 A1
(43) Pub. Date: Mar. 2, 2023

(54) ISOLATION TRENCH STRUCTURE OF BACKSIDE ILLUMINATED CMOS IMAGE SENSOR AND METHOD FOR MANUFACTURING THE SAME

(71) Applicant: Shanghai Huali Integrated Circuit Corporation, Shanghai (CN)

(72) Inventors: Linghao Xiong, Shanghai (CN); Feng Ji, Shanghai (CN); Haoyu Chen, Shanghai (CN); Qiwei Wang, Shanghai (CN)

(21) Appl. No.: 17/880,280

(22) Filed: Aug. 3, 2022

(30) Foreign Application Priority Data
Aug. 31, 2021 (CN) 202111010037.9

(51) Int. Cl. H01L 27/146

(52) U.S. Cl. CPC H01L 27/1463; H01L 27/14645; H01L 27/14621; H01L 27/14627; H01L 27/1464; H01L 27/14683

(57) ABSTRACT

An isolation trench structure for a backside illuminated CMOS image sensor is disclosed. Each pixel cell in the backside illuminated CMOS image sensor comprises a photodiode and a cell isolation trench structure. A first cell trench combination structure containing more than five first cell trenches is formed in each active area, the cell isolation trench structure is formed in the first cell trench of the first cell trench combination structure, and the first cell trench extends longitudinally through an N-type area of the photodiode or is located in the N-type area of the photodiode. In a plan view, first ends of all the first cell trenches converge toward the center of the active area, and second ends of all the first cell trenches diverge from each other toward the edge of the active area, so as to divide the active area into a plurality of active area subblocks.

### CROSS-REFERENCES TO RELATED APPLICATIONS

This application claims the priority to Chinese patent application No. CN 202111010037.9, filed on Aug. 31, 2021, and entitled “ISOLATION TRENCH STRUCTURE OF BACKSIDE ILLUMINATED CMOS IMAGE SENSOR AND METHOD FOR MANUFACTURING THE SAME”, the disclosure of which is incorporated herein by reference in entirety.

### TECHNICAL FIELD

The present application relates to the field of semiconductor integrated circuit manufacturing, in particular, to an isolation trench structure of a backside illuminated (BSI) CMOS image sensor (CIS). The present application also relates to a method for manufacturing an isolation trench structure of the backside illuminated CMOS image sensor.

### BACKGROUND

The existing CMOS image sensor includes a pixel cell circuit and a CMOS circuit. The pixel cell circuit is located in a pixel area, and the CMOS circuit is a logic circuit located in a logic circuit area. Compared with the CCD image sensor, the CMOS image sensor may have a higher integration degree from the CMOS standard manufacturing process, can be integrated with other digital-analog operation and control circuits on the same chip, and thus is more applicable to many applications.

According to the number of transistors included in the pixel cell circuit of the existing CMOS image sensor, the existing CMOS image sensors are mainly classified into 3T-type structures and 4T-type structures.

FIG. 1 is a schematic diagram of an equivalent circuit of a pixel cell circuit of an existing 3T-type CMOS image sensor. The pixel cell circuit of the existing 3T-type CMOS image sensor includes a photodiode D1 and a CMOS pixel readout circuit. The CMOS pixel readout circuit is a 3T-type pixel circuit, including a reset transistor M1, an amplification transistor M2, and a selection transistor M3, all of which are NMOS transistors.

An N-type area of the photodiode D1 is connected to the source of the reset transistor M1.

The gate of the reset transistor M1 is connected to a reset signal Reset, and the reset signal Reset is a voltage pulse. When the reset signal Reset is at a high level, the reset transistor M1 is turned on and absorbs electrons of the photodiode D1 into the power supply Vdd of the readout circuit, so as to achieve reset. When irradiated by light, the photodiode D1 generates photo-generated electrons, the voltage increases, and an electrical signal is transmitted via an amplification circuit M2. The gate of the selection transistor M3 is connected to a row selection signal Rs, so as to select an amplified electrical signal for outputting, i.e., an output signal Vout.

FIG. 2 is a schematic diagram of an equivalent of a pixel cell circuit of an existing 4T-type CMOS image sensor. The structure shown in FIG. 2 differs from the structure shown in FIG. 1 for its additional transfer transistor, which is also referred to as a transmission transistor M4. The source area of the transfer transistor M4 is an N-type area connected to the photodiode D1, the drain area of the transfer transistor M4 is a floating diffusion (FD) area, and the gate of the transfer transistor M4 is connected to a transmission control signal Tx. The photo-generated electrons by the photodiode D1 are transferred to the floating diffusion area via the transfer transistor M4, and then signal amplification is achieved by connecting the floating diffusion area to the gate of the amplification transistor M2.

The CMOS image sensors are classified as frontside illuminated (FSI) CMOS image sensors and backside illuminated CMOS image sensors according to their different light entering paths.

The light entering path in the frontside illuminated CMOS image sensor passes through a plurality of metal interconnection layers. Since the metal layers are opaque, the incident light is blocked or reflected in the metal layers, so that the amount of incident light that actually enters the photodiode is significantly reduced.

In the backside illuminated CMOS image sensor, a color filter and a microlens are directly formed on the backside of the photodiode. Since the metal interconnection layer is located on the frontside of a semiconductor substrate, the light entering path does not pass through the metal interconnection layers, and the amount of incident light that actually enters the photodiode is not reduced much.

With continuous shrinking of the process node of semiconductor integrated circuit manufacturing technologies, the device sizes keep on decreasing continuously, and dimensions of a pixel cell of the BSI CIS, including the longitudinal dimension and the lateral dimension, have also been shrinking. The reduction of the lateral dimension is prone to causing crosstalk between adjacent pixel cells. In addition to the crosstalk, the reduction of the longitudinal dimension shortens the absorption path of the infrared light, thereby reducing the quantum efficiency (QE) of red light.

### BRIEF SUMMARY

The present application provides an isolation trench structure in a backside illuminated CMOS image sensor, which can improve the quantum efficiency of red light, thereby facilitating the reduction of the CIS device size. The present application also provides a method for manufacturing an isolation trench structure of a backside illuminated CMOS image sensor.

The present application provides an isolation trench structure of a backside illuminated CMOS image sensor. The backside illuminated CMOS image sensor is formed on a semiconductor substrate, a plurality of pixel cells are formed in a pixel area of the backside illuminated CMOS image sensor, and each of the pixel cells is respectively formed in an active area.

Each of the pixel cells includes a photodiode and a cell isolation trench structure; and the cell isolation trench structure is a part of the isolation trench structure.

A first cell trench combination structure formed by more than five first cell trenches is formed in each of the active areas, the cell isolation trench structure is formed in the first cell trench of the first cell trench combination structure, and the first cell trench is formed by etching the backside of the semiconductor substrate.

The photodiode is a longitudinal stack structure having an N-type area and a P-type area formed in the active area.

The first cell trench extends longitudinally through the N-type area of the photodiode or is located in the N-type area of the photodiode.

In a plan view, first ends of all the first cell trenches in the first cell trench combination structure converge toward the center of the active area, second ends of all the first cell trenches diverge from each other toward the edge of the active area, and two adjacent first cell trenches have an included angle.

An outline of the first cell trench combination structure is formed by connecting the second ends of the first cell trenches, and the active area within the outline of the first cell trench combination structure is divided into a plurality of active area subblocks by the first cell trenches; a light travel distance in the active area subblock is increased under a reflection action of a material layer of the cell isolation trench structure in the first cell trench on two sides of the active area subblock, and a total increase amount of the light travel distance in the active area is the sum of increase amounts of the light travel distances in all the active area subblocks.

In one example, the semiconductor substrate includes a silicon substrate.

In one example, the isolation trench structure further includes a deep trench isolation structure formed between the active areas of all the pixel cells, the deep trench isolation structure is formed in a second intercell trench, and the second intercell trench is formed by etching the backside of the semiconductor substrate.

In one example, the material of the cell isolation trench structure includes an oxide layer, a nitride layer, or a high dielectric constant layer.

In one example, the material of the deep trench isolation structure includes an oxide layer, a nitride layer, or a high dielectric constant layer.

In one example, the semiconductor substrate is P-type doped, an N-type epitaxial layer is formed on the frontside of the semiconductor substrate, the N-type area of the photodiode includes the N-type epitaxial layer of a formation area of the photodiode, and the N-type area of the photodiode includes the semiconductor substrate of the formation area of the photodiode.

In one example, the pixel cell further includes a CMOS pixel reading circuit, the CMOS pixel reading circuit being used to read photo-generated electrons of the photodiode; and

a color filter and a microlens are formed on the backside of the pixel cell.

In one example, the depth of the second intercell trench is greater than the depth of the first cell trench.

In one example, the included angles between the first cell trenches in the first cell trench combination structure are equal.

In order to solve the above technical problems, the present application provides a method for manufacturing an isolation trench structure of a backside illuminated CMOS image sensor, including the following steps:

step 1, forming a frontside structure of the backside illuminated CMOS image sensor on a semiconductor substrate, wherein in the frontside structure of the backside illuminated CMOS image sensor, the backside illuminated CMOS image sensor includes a plurality of pixel cells located in a pixel area, each of the pixel cells is respectively formed in an active area, each of the pixel cells includes a photodiode, and the photodiode is a longitudinal stack structure composed of an N-type area and a P-type area formed in the active area;

step 2, forming a first photoresist pattern on the backside of the semiconductor substrate;

step 3, etching the backside of the semiconductor substrate under the definition of the first photoresist pattern to form a first cell trench,

wherein more than five first cell trenches are formed in each of the active areas, and all of the first cell trenches form a first cell trench combination structure;

the first cell trench extends longitudinally through the N-type area of the photodiode or is located in the N-type area of the photodiode;

in a plan view, first ends of all the first cell trenches in the first cell trench combination structure converge toward the center of the active area, second ends of all the first cell trenches diverge from each other toward the edge of the active area, and two adjacent first cell trenches have an included angle;

an outline of the first cell trench combination structure is formed by connecting the second ends of the first cell trenches, and the active area within the outline of the first cell trench combination structure is divided into a plurality of active area subblocks by the first cell trenches; and

step 4: performing material filling in each of the first cell trenches of the first cell trench combination structure to form a cell isolation trench structure, wherein the cell isolation trench structure is a part of the isolation trench structure;

a light travel length (distance) in the active area subblock is increased under a reflection action of a material layer of the cell isolation trench structure in the first cell trench on two sides of the active area subblock, and a total increase amount of the light travel distance in the active area is the sum of increase amounts of the light travel distances in all the active area subblocks.

In one example, the semiconductor substrate includes a silicon substrate.

In one example, the isolation trench structure further includes a deep trench isolation structure formed between all the pixel cells; and forming the deep trench isolation structure includes sub-steps of:

forming a second photoresist pattern on the backside of the semiconductor substrate;

etching the frontside of the semiconductor substrate under the definition of the second photoresist pattern to form a second intercell trench; and

performing material filling in the second intercell trench to form the deep trench isolation structure.

In one example, the material of the cell isolation trench structure includes an oxide layer, a nitride layer, or a high dielectric constant layer.

In one example, the material of the deep trench isolation structure includes an oxide layer, a nitride layer, or a high dielectric constant layer.

In one example, the semiconductor substrate is P-type doped, an N-type epitaxial layer is formed on the frontside of the semiconductor substrate, the N-type area of the photodiode includes the N-type epitaxial layer of a formation area of the photodiode, and the N-type area of the photodiode includes the semiconductor substrate of the formation area of the photodiode.

In one example, the depth of the second intercell trench is greater than the depth of the first cell trench.

In one example, the included angles between the first cell trenches in the first cell trench combination structure are equal.

The present application provides a particular configuration for a top view structure of the first cell trench combination structure of the cell isolation trench structure formed in the pixel cell. i.e., a configuration where the first ends of all the first cell trenches in the first cell trench combination structure converge toward the center of the active area and the second ends diverge from each other toward the edge of the active area. Such the structure facilitates the division into the plurality of active area subblocks, and facilitates the configuration of the number of the active area subblocks as needed. For example, the number of the active area subblocks can be increased by increasing the number of the first cell trenches and reducing the included angle between the first cell trenches. The material layer of the cell isolation trench structure in the first cell trench on two sides of each active area subblock forms an optical reflection surface, facilitating the propagation of light from the backside of each active area subblock to the inside and thereby increasing the light travel distance By increasing the number of the active area subblocks, the total increase amount of the light travel distance in the active area can be increased, eventually improving the quantum efficiency of red light and thereby facilitating the decrease of the device size.

Based on the configuration of the deep trench isolation structure arranged between the pixel cells, the crosstalk between the pixel cells will meet the device requirements.

### BRIEF DESCRIPTION OF THE DRAWINGS

The present application is described in detail below with reference to the drawings and specific implementations:

FIG. 1 is a schematic diagram of an equivalent pixel cell circuit for the existing 3T-type CMOS image sensor.

FIG. 2 is a schematic diagram of an equivalent pixel cell circuit for the existing 4T-type CMOS image sensor.

FIG. 3 is a schematic structural diagram of the first kind of existing backside illuminated CMOS image sensor.

FIG. 4 is a schematic structural diagram of the second kind of existing backside illuminated CMOS image sensor.

FIG. 5A is a schematic structural diagram of the third kind of existing backside illuminated CMOS image sensor.

FIG. 5B illustrates a layout structure of a cell isolation trench structure in FIG. 5A.

FIG. 6A is a simulated signal image of incident light crosstalk in the first kind of existing backside illuminated CMOS image sensor corresponding to FIG. 3.

FIG. 6B is a simulated signal image of incident light crosstalk in the second kind of existing backside illuminated CMOS image sensor corresponding to FIG. 4.

FIG. 6C is a simulated signal image of incident light crosstalk in the third kind of existing backside illuminated CMOS image sensor corresponding to FIG. 5A.

FIG. 7A is a schematic structural diagram of an isolation trench structure of a backside illuminated CMOS image sensor according to an embodiment of the present application.

FIG. 7B illustrates a layout structure of the cell isolation trench structure in FIG. 7A.

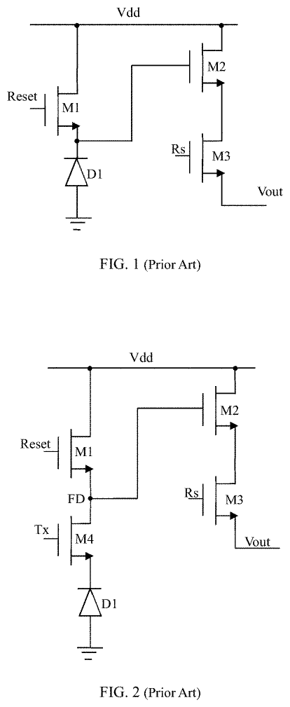

### DETAILED DESCRIPTION OF THE DISCLOSURE

An isolation trench structure of a backside illuminated CMOS image sensor in the embodiment of the present application is obtained on the basis of analyzing the defects of an existing isolation trench structure of a backside illuminated CMOS image sensor. Therefore, before the introduction of the isolation trench structure of a backside illuminated CMOS image sensor in the embodiment of the present application in detail, the existing three types of an isolation trench structure of a backside illuminated CMOS image sensor are introduced first and analyzed accordingly:

The First Kind of Existing Backside Illuminated CMOS Image Sensor

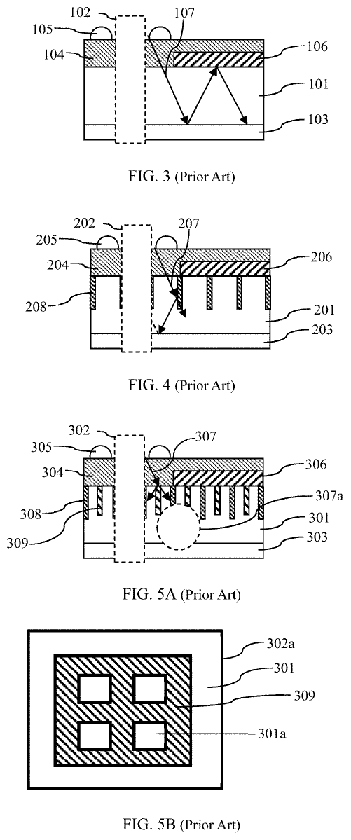

FIG. 3 is a schematic structural diagram of the first kind of existing backside illuminated CMOS image sensor. The backside illuminated CMOS image sensor is formed on a semiconductor substrate 101, a plurality of active areas are formed on the semiconductor substrate 101, and pixel cells in a pixel area are respectively formed in the active areas. The active area of the pixel cell in FIG. 3 is located in the semiconductor substrate 101 in the dashed line box 102. A photodiode and a CMOS pixel readout circuit are formed in the pixel cell.

A metal interconnection layer 103 is formed on the frontside of the semiconductor substrate 101. A color filter 104 and a microlens 105 are formed on the backside of the semiconductor substrate 101. Moreover, in some areas of the backside illuminated CMOS image sensor where light collection is not required, a light blocking layer 106 needs to be formed in these areas.

Since the first kind of existing backside illuminated CMOS image sensor does not adopt a deep trench isolation (DTI) structure, incident light 107 easily enters the adjacent pixel cell, thereby causing relatively large crosstalk. The incident light 107 shown in FIG. 3 easily enters the adjacent pixel cell at the bottom of the light blocking layer 106.

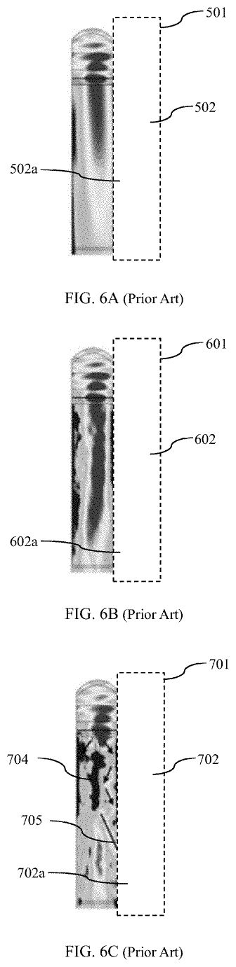

FIG. 6A is a simulated signal image of incident light crosstalk in the first kind of existing backside illuminated CMOS image sensor corresponding to FIG. 3. In FIG. 6A, the dashed line box 501 corresponds to an area where the light blocking layer 106 is provided, and there is light entering the pixel cell on the left side of the dashed line box 501. If there is no crosstalk, the semiconductor substrate corresponding to the dashed line box 501 should be a dark area corresponding to the mark 502. However, an actual simulation result indicates that a relatively large bright area corresponding to the mark 502a appears in the dashed line box 501. Obviously, the bright area corresponding to the mark 502a is formed by the incident light crosstalk in the pixel cell on the left side.

The Second Kind of Existing Backside Illuminated CMOS Image Sensor

FIG. 4 is a schematic structural diagram of the second kind of existing backside illuminated CMOS image sensor. The second kind of existing backside illuminated CMOS image sensor also includes a semiconductor substrate 201. The dashed line box 202 corresponds to the range of one pixel cell in a pixel area, and a metal interconnection layer 203 is located on the backside of the semiconductor substrate 201. A color filter 204, a microlens 205, and a light blocking layer 206 are formed on the frontside of the semiconductor substrate 201.

The second kind of existing backside illuminated CMOS image sensor differs from the first kind of existing backside illuminated CMOS image sensor in that the DTI 208 is provided between active areas corresponding to the pixel cells. The DTI 208 can reduce crosstalk of incident light 207 between different pixel cells.

FIG. 6B is a simulated signal image of incident light crosstalk in the second kind of existing backside illuminated CMOS image sensor corresponding to FIG. 4. In FIG. 6B, the dashed line box 601 corresponds to an area where the light blocking layer 206 is provided, and there is light entering the pixel cell on the left side of the dashed line box 601. If there is no crosstalk, the semiconductor substrate corresponding to the dashed line box 601 should be a dark area corresponding to the mark 602. However, an actual simulation result indicates that a small bright area corresponding to the mark 602a appears in the dashed line box 601. Compared with FIG. 6A, the bright area corresponding to the mark 602a is obviously much smaller than the bright area corresponding to the mark 502a. Therefore, the second kind of existing backside illuminated CMOS image sensor can significantly reduce the crosstalk.

The Third Kind of Existing Backside Illuminated CMOS Image Sensor

FIG. 5A is a schematic structural diagram of the third kind of existing backside illuminated CMOS image sensor. The third kind of existing backside illuminated CMOS image sensor also includes a semiconductor substrate 301. The dashed line box 302 corresponds to the range of one pixel cell in a pixel area, and a metal interconnection layer 303 is located on the backside of the semiconductor substrate 301. A color filter 304, a microlens 305, and a light blocking layer 306 are formed on the frontside of the semiconductor substrate 301. DTI 308 is provided between the active areas corresponding to the pixel cells.

The third kind of existing backside illuminated CMOS image sensor differs from the second kind of existing backside illuminated CMOS image sensor in that CDTI 309 is provided in the active area corresponding to the pixel cell. FIG. 5B illustrates a layout structure of a cell isolation trench structure in FIG. 5A. A box corresponding to the mark 302a is an edge box of the active area of the pixel cell. The active area includes the semiconductor substrate 301 within the range of the active area. The periphery of the block 302a is the DTI 308, which is not shown in FIG. 5B. It can be seen that the layout structure of the CDTI 309 is in the shape of a cross, and the cell isolation trench structure divides the active area inside the cell isolation trench structure into four active area subblocks 301a.

FIG. 6C is a simulated signal image of incident light crosstalk in the third kind of existing backside illuminated CMOS image sensor corresponding to FIG. 5A. In FIG. 6C, the dashed line box 701 corresponds to an area where the light blocking layer 306 is provided, and there is light entering the pixel cell on the left side of the dashed line box 701. If there is no crosstalk, the semiconductor substrate corresponding to the dashed line box 701 should be a dark area corresponding to the mark 702. However, an actual simulation result indicates that a relatively large bright area corresponding to the mark 702a appears in the dashed line box 701. Compared with FIG. 6B, the bright area corresponding to the mark 702a is obviously larger than the bright area corresponding to the mark 602a.

In the range of the active area subblock 301a corresponding to FIG. 5B, the incident light 307 shown in FIG. 5A propagates downward under the reflection of a material layer of the cell isolation trench structure on the periphery, thereby increasing a light travel distance. Since the wavelength of red light is relatively large, the increase of the light travel distance facilitates the absorption of red light, thereby improving the quantum efficiency of red light. However, it is found from experiments that the third kind of existing backside illuminated CMOS image sensor achieves limited improvement in the quantum efficiency of red light.

In addition, the bright area corresponding to the mark 702a is obviously larger the bright area corresponding to the mark 602a, that is, the crosstalk is increased after the CDTI 309 is introduced. As shown by the dashed line circle 307a in FIG. 5A, at the bottom of the CDTI 309, the light 307 is easily reflected and enters the adjacent pixel cell. The dark area corresponding to the mark 604 in FIG. 6C is a formation area of the CDTI 309, and it can be seen that the CDTI 309 facilitates downward propagation of light. However, at the bottom of the dark area 604, light 605 is easily reflected and enters the adjacent area 602a, so the introduction of the CDTI 309 eventually increases the crosstalk.

Isolation trench structure of a backside illuminated CMOS image sensor in the embodiment of the present application:

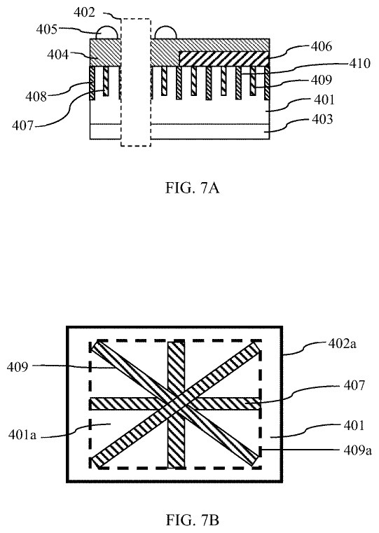

FIG. 7A is a schematic structural diagram of the isolation trench structure of a backside illuminated CMOS image sensor according to the embodiment of the present application. FIG. 7B illustrates a layout structure of a cell isolation trench structure 407 in FIG. 7A. In the isolation trench structure of a backside illuminated CMOS image sensor according to the embodiment of the present application, the backside illuminated CMOS image sensor is formed on a semiconductor substrate 401, a plurality of pixel cells are formed in a pixel area of the backside illuminated CMOS image sensor, and each of the pixel cells is respectively formed in an active area. In FIG. 7A, the active area of the pixel cell is located in the semiconductor substrate 401 in the dashed line box 402.

Each of the pixel cells includes a photodiode (not shown in these cross sectional figures) and a cell isolation trench structure 407; and the cell isolation trench structure 407 is a part of the isolation trench structure.

A first cell trench combination structure formed by more than five first cell trenches 409 is formed in each of the active areas, the cell isolation trench structure 407 is formed in the first cell trench 409 of the first cell trench combination structure, and the first cell trench 409 is formed by etching the backside of the semiconductor substrate 401.

The photodiode is a longitudinal stack (perpendicular to the substrate) structure composed of an N-type area and a P-type area formed in the active area.

The first cell trench 409 extends longitudinally (vertically in the cross sectional view) through the N-type area of the photodiode or is located in the N-type area of the photodiode.

In a plan view, first ends of all the first cell trenches in the first cell trench 409 combination structure converge toward the center of the active area, second ends of all the first cell trenches 409 diverge from each other toward the edge of the active area, and two adjacent first cell trenches 409 have an included angle. In the embodiment of the present application, the included angles between the first cell trenches 409 in the first cell trench combination structure are equal. Eight first cell trenches 409 with the first ends thereof connected together are shown in FIG. 7B.

A dashed outline 409a of the first cell trench combination structure is formed by connecting the second ends of the first cell trenches 409, and the active area within the outline 409a of the first cell trench combination structure is divided into a plurality of active area subblocks 401a by the first cell trenches409. light travel distance in the active area subblock 401a is increased under a reflection action of a material layer of the cell isolation trench structure 407 in the first cell trench 409 on two sides of the active area subblock 401a, and a total increase amount of the light travel distance in the active area is the sum of increase amounts of the light travel lengths in all the active area subblocks 401a.

The semiconductor substrate 401 includes a silicon substrate.

The isolation trench structure further includes a deep trench isolation structure 408 formed between the active areas of all the pixel cells, the deep trench isolation structure 408 is formed in a second intercell trench 410, and the second intercell trench 410 is formed by etching the backside of the semiconductor substrate 401.

The material of the cell isolation trench structure 407 includes an oxide layer, a nitride layer, or a high dielectric constant layer.

The material of the deep trench isolation structure 408 includes an oxide layer, a nitride layer, or a high dielectric constant layer.

The semiconductor substrate 401 is P-type doped, an N-type epitaxial layer is formed on the frontside of the semiconductor substrate 401, the N-type area of the photodiode includes the N-type epitaxial layer in a formation area of the photodiode, and the N-type area of the photodiode includes the semiconductor substrate 401 of the formation area of the photodiode.

The pixel cell further includes a CMOS pixel reading circuit (not shown), and the CMOS pixel reading circuit is used to read photo-generated electrons of the photodiode.

The depth of the second intercell trench 408 is greater than the depth of the first cell trench 409. The backside of the deep trench isolation structure 408 is flush with the backside of the cell isolation trench structure 407, and the top surface of the deep trench isolation structure 408 is higher than the top surface of the cell isolation trench structure 407.

A color filter 404 and a microlens 405 are formed on the backside of the pixel cell. Moreover, a light blocking layer 406 is formed in some areas of the backside illuminated CMOS image sensor where light collection is not required.

A metal interconnection layer 403 is formed on the frontside of the semiconductor substrate 401.

Referring to FIG. 7B, a box corresponding to the mark 402a is an edge box of the active area of the pixel cell. The active area includes the semiconductor substrate 401 within the range of the active area. An epitaxial layer may be formed on the semiconductor substrate 401 as needed, and in this case, the active area includes the epitaxial layer on the surface of the semiconductor substrate 401 within the range of the active area. The periphery of the block 402a is the deep trench isolation structure 408, and the deep trench isolation structure 408 is not shown in FIG. 7B. It can be seen that the eight first cell trenches 409 eventually form a cross and saltire shape and divide the active area into eight active area subblocks 401a. Compared with the four active area subblocks 301a in FIG. 5B, the number of the active area subblocks 401a in the embodiment of the present application is increased, eventually increasing the total increase amount of the light travel length in the active area and thereby improving the quantum efficiency of red light.

The present application provides a particular configuration for a top view structure of the first cell trench 409 combination structure of the cell isolation trench structure 407 formed in the pixel cell. i.e., a configuration where the first ends of all the first cell trenches 409 in the first cell trench 409 combination structure converge toward the center of the active area and the second ends diverge from each other toward the edge of the active area. Such the structure facilitates the division into the plurality of active area subblocks, and facilitates the configuration of the number of the active area subblocks as needed. For example, the number of the active area subblocks can be increased by increasing the number of the first cell trenches 409 and reducing the included angle between the first cell trenches 409. The material layer of the cell isolation trench structure 407 in the first cell trench 409 on two sides of each active area subblock forms an optical reflection surface, facilitating the propagation of light from the backside of each active area subblock to the inside and thereby increasing the light travel length. By increasing the number of the active area subblocks, the total increase amount of the light travel distance in the active area can be increased, eventually improving the quantum efficiency of red light and thereby facilitating the decrease of the device size.

Because the configuration of the deep trench isolation structure 408 is arranged between the pixel cells, the crosstalk between the pixel cells can satisfy the requirements.

Method for manufacturing an isolation trench structure of a backside illuminated CMOS image sensor in the embodiment of the present application:

The method for manufacturing an isolation trench structure of a backside illuminated CMOS image sensor in the embodiment of the present application includes the following steps.

Step 1. A frontside structure of the backside illuminated CMOS image sensor is formed on a semiconductor substrate 401, wherein in the frontside structure of the backside illuminated CMOS image sensor, the backside illuminated CMOS image sensor includes a plurality of pixel cells located in a pixel area, each of the pixel cells is respectively formed in an active area, each of the pixel cells includes a photodiode, and the photodiode is a longitudinal stack structure composed of an N-type area and a P-type area formed in the active area.

In the embodiment of the present application, the semiconductor substrate 401 includes a silicon substrate.

The pixel cell further includes a CMOS pixel reading circuit, and the CMOS pixel reading circuit is used to read photo-generated electrons of the photodiode.

Step 2. A first photoresist pattern is formed on the backside of the semiconductor substrate 401, wherein the first photoresist pattern is defined by means of a photomask.

Step 3. The backside of the semiconductor substrate 401 is etched under the definition of the first photoresist pattern to form a first cell trench 409.

More than five first cell trenches 409 are formed in each of the active areas, and all of the first cell trenches 409 form a first cell trench combination structure.

The first cell trench 409 extends longitudinally through the N-type area of the photodiode or is located in the N-type area of the photodiode.

In a plan view, first ends of all the first cell trenches 409 in the first cell trench combination structure converge toward the center of the active area, second ends of all the first cell trenches 409 diverge from each other toward the edge of the active area, and two adjacent first cell trenches 409 have an included angle. In method of the embodiment of the present application, the included angles between the first cell trenches 409 in the first cell trench combination structure are equal. In a method of other embodiments, the included angles between the first cell trenches 409 in the first cell trench combination structure can be unequal.

An outline 409a of the first cell trench combination structure is formed by connecting the second ends of the first cell trenches 409, and the active area within the outline 409a of the first cell trench combination structure is divided into a plurality of active area subblocks 401a by the first cell trenches 409.

Step 4. Material filling is performed in each of the first cell trenches 409 of the first cell trench combination structure to form a cell isolation trench structure 407, wherein the cell isolation trench structure 407 is a part of the isolation trench structure.

The material of the cell isolation trench structure 407 includes an oxide layer, a nitride layer, or a high dielectric constant layer.

A light travel length in the active area subblock 401a is increased by the reflection from a material layer of the cell isolation trench structure 407 in the first cell trench 409 on two sides of the active area subblock 401a, and a total increase amount of the light travel length in the active area is the sum of increase amounts of the light travel lengths in all the active area subblocks 401a.

The isolation trench structure further includes a deep trench isolation structure 408 formed between all the pixel cells, and the deep trench isolation structure 408 belongs to the backside structure of the backside illuminated CMOS image sensor. Forming the deep trench isolation structure 408 includes the following sub-steps:

A second photoresist pattern on the backside of the semiconductor substrate 401.

The frontside of the semiconductor substrate 401 is etched under the definition of the second photoresist pattern to form a second intercell trench 410. In the method of the embodiment of the present application, the depth of the second intercell trench 410 is greater than the depth of the first cell trench 409.

Material filling is performed in the second intercell trench 410 to form the deep trench isolation structure 408.

The material of the deep trench isolation structure 408 includes an oxide layer, a nitride layer, or a high dielectric constant layer.

The semiconductor substrate 401 is P-type doped, an N-type epitaxial layer is formed on the frontside of the semiconductor substrate 401, the N-type area of the photodiode includes the N-type epitaxial layer of a formation area of the photodiode, and the N-type area of the photodiode includes the semiconductor substrate 401 of the formation area of the photodiode.

In the method of the embodiment of the present application, the isolation trench structure includes the cell isolation trench structure 407 located in the pixel cell and the deep trench isolation structure 408 located between the pixel cells.

The method further includes the following backside process:

A color filter and a microlens are formed on the backside of the pixel cell.

The present application is described in detail above by using specific embodiments, which, however, are not intended to limit the present application. Without departing from the principles of the present application, those skilled in the art can also make many modifications and improvements, which should also be regarded as the scope of protection of the present application.

What is claimed is:

1. An isolation trench structure of a backside illuminated CMOS image sensor, wherein the backside illuminated CMOS image sensor is formed on a backside of a semiconductor substrate,
wherein a plurality of pixel cells is formed in a pixel area in one of active areas of the backside illuminated CMOS image sensor respectively;
wherein each of the plurality of pixel cells comprises a photodiode and a cell isolation trench structure which is a part of the isolation trench structure;
wherein the backside illuminated CMOS image sensor comprises a first cell trench combination structure comprising N first cell trenches in each of the active areas, wherein N is an integer larger than 5;
wherein the cell isolation trench structure is disposed in a first of the N cell trench in the first cell trench combination structure, and wherein the first cell trench is formed by etching the backside of the semiconductor substrate;
wherein the photodiode comprises a longitudinal stack structure having an N-type area and a P-type area formed in each of the active areas;
wherein each of the N first cell trenches extends longitudinally through the N-type area of the photodiode or is located in the N-type area of the photodiode;
wherein in a plan view, first ends of all of the N first cell trenches in the first cell trench combination structure converge toward a center of said active area, second ends of all the N first cell trenches diverge from each other toward edges of said active area, and wherein two adjacent first of the N cell trenches have an included angle;
wherein an outline of the first cell trench combination structure is formed by connecting the second ends of the first of the N cell trenches, wherein said active area within the outline of the first cell trench combination structure is divided into a plurality of active area sub-blocks by the first of the N cell trenches; and
wherein a light travel distance in the active area subblock is increased under a reflection from a material layer of the cell isolation trench structure in the first of the N cell trenches on two sides of the active area subblock, and a total increase amount of the light travel distance in the active area is a sum of increase amounts of the light travel distance in all the active area subblocks.

2. The isolation trench structure of the backside illuminated CMOS image sensor according to claim 1, wherein the semiconductor substrate comprises a silicon substrate.

3. The isolation trench structure of the backside illuminated CMOS image sensor according to claim 1, wherein the isolation trench structure further comprises a deep trench isolation structure formed between two of the active areas of the plurality of pixel cells, wherein the deep trench isolation structure is formed in a second intercell trench, and wherein the second intercell trench is formed by etching the backside of the semiconductor substrate.

4. The isolation trench structure of the backside illuminated CMOS image sensor according to claim 1, wherein a material of the cell isolation trench structure comprises an oxide layer, a nitride layer, or a high dielectric constant layer.

5. The isolation trench structure of the backside illuminated CMOS image sensor according to claim 3, wherein a material of the deep trench isolation structure comprises an oxide layer, a nitride layer, or a high dielectric constant layer.

6. The isolation trench structure of the backside illuminated CMOS image sensor according to claim 1, wherein the semiconductor substrate is P-type doped, wherein an N-type epitaxial layer is formed on a frontside of the semiconductor substrate, wherein the N-type epitaxial layer is in an N-type area of the photodiode, and wherein the N-type area of the photodiode is disposed in the N-type area of the semiconductor substrate.

7. The isolation trench structure of the backside illuminated CMOS image sensor according to claim 1, wherein the plurality of pixel cells further comprises a CMOS pixel reading circuit, wherein the CMOS pixel reading circuit reads photo-generated electrons in the photodiode; and
wherein each of the plurality of pixel cells further comprises a color filter and a microlens on a backside.

8. The isolation trench structure of the backside illuminated CMOS image sensor according to claim 3, wherein a depth of the second intercell trench is greater than a depth of the first cell trench.

9. The isolation trench structure of the backside illuminated CMOS image sensor according to claim 1, wherein included angles between the N first cell trenches in the first cell trench combination structure are equal.

10. A method for manufacturing an isolation trench structure of a backside illuminated CMOS image sensor, comprising following steps:
step 1, forming a frontside structure of the backside illuminated CMOS image sensor on a semiconductor substrate, wherein in the frontside structure of the backside illuminated CMOS image sensor, wherein the backside illuminated CMOS image sensor comprises a plurality of pixel cells located in a pixel area, wherein each of the plurality of pixel cells is respectively formed in an active area, wherein each of the plurality of pixel cells comprises a photodiode, wherein an active area of the photodiode is a longitudinal stack structure comprising an N-type area and a P-type area;
step 2, forming a first photoresist pattern on a backside of the semiconductor substrate;
step 3, etching the backside of the semiconductor substrate under a definition of the first photoresist pattern to form N first cell trenches,
wherein the N five first cell trenches are formed in each of the active areas, and all of the N first cell trenches form a first cell trench combination structure;
wherein one of the N first cell trench extends longitudinally through the N-type area of the photodiode or is located in the N-type area of the photodiode;
wherein in a plan view, first ends of all the N first cell trenches in the first cell trench combination structure converge toward a center of the active area, second ends of all the N first cell trenches diverge from each other toward an edge of the active area, and two adjacent of the N first cell trenches have an included angle;
wherein an outline of the first cell trench combination structure is formed by connecting the second ends of the first cell trenches, and the active area within the outline of the first cell trench combination structure is divided into active area subblocks by the first cell trenches; and
step 4: performing material filling in each of the first cell trenches of the first cell trench combination structure to form a cell isolation trench structure, wherein the cell isolation trench structure is a part of an isolation trench structure;
where a light travel distance in the active area subblocks is increased under a reflection action of a material layer of the cell isolation trench structure in the first cell trench on two sides of the active area subblock, and a total increase amount of the light travel distance in the active area is a sum of increase amounts of the light travel distance in all the active area subblocks.

11. The method for manufacturing the isolation trench structure of the backside illuminated CMOS image sensor according to claim 10, wherein the semiconductor substrate comprises a silicon substrate.

12. The method for manufacturing the isolation trench structure of the backside illuminated CMOS image sensor according to claim 10, wherein the isolation trench structure further comprises a deep trench isolation structure formed between all the plurality of pixel cells; and wherein forming the deep trench isolation structure comprises sub-steps of:
forming a second photoresist pattern on the backside of the semiconductor substrate;
etching a frontside of the semiconductor substrate under a definition of the second photoresist pattern to form a second intercell trench; and
performing material filling in the second intercell trench to form the deep trench isolation structure.

13. The method for manufacturing the isolation trench structure of the backside illuminated CMOS image sensor according to claim 10, wherein the material of the cell isolation trench structure comprises an oxide layer, a nitride layer, or a high dielectric constant layer.

14. The method for manufacturing the isolation trench structure of the backside illuminated CMOS image sensor according to claim 12, wherein the material of the deep trench isolation structure comprises an oxide layer, a nitride layer, or a high dielectric constant layer.

15. The method for manufacturing the isolation trench structure of the backside illuminated CMOS image sensor according to claim 10, wherein the semiconductor substrate is P-type doped, an N-type epitaxial layer is formed on the frontside of the semiconductor substrate, wherein the N-type area of the photodiode comprises a N-type epitaxial layer of a formation area of the photodiode, and the N-type area of the photodiode comprises the semiconductor substrate of the formation area of the photodiode.

16. The method for manufacturing the isolation trench structure of the backside illuminated CMOS image sensor according to claim 12, wherein a depth of the second intercell trench is greater than a depth of the N first cell trench, and wherein N is an integer larger than 5.

17. The method for manufacturing the isolation trench structure of the backside illuminated CMOS image sensor according to claim 10, wherein included angles between two of the N first cell trenches in the first cell trench combination structure are equal.
